(19) United States
(12) Patent Application Publication
(10) Pub. No.: US 2006/0138087 A1
(43) Pub. Date: Jun. 29, 2006

(54) Copper containing abrasive particles to modify reactivity and performance of copper CMP slurries

(76) Inventors: Harsono S. Simka, Saratoga, CA (US); Sadasivan Shankar, Cupertino, CA (US); Lei Jiang, Camas, WA (US); Paul Fischer, Portland, OR (US); Anne F. Miller, Portland, OR (US); Kenneth C. Cadien, Portland, OR (US)

Correspondence Address: BLAKELY SOKOLOFF TAYLOR & ZAFMAN, 12400 WILSHIRE BOULEVARD, SEVENTH FLOOR, LOS ANGELES, CA, 90025-1030, US

(21) Appl. No.: 11/026,322

(22) Filed: Dec. 29, 2004

(51) Int. Cl. C09K 13/00; C03C 15/00; H01L 21/302; B44C 1/22

(52) U.S. Cl. 216/88; 438/692; 252/79.1; 216/89

(57) ABSTRACT

A slurry for use in a chemical mechanical polishing process for planarizing copper-based metal structures on a substrate comprises an oxidizer, an organic complexing agent, surfactants, and a plurality of copper-based metal abrasive particles, wherein the copper in the copper-based metal is capable of dissolving into the slurry and forming copper ion complexes. During the chemical mechanical polishing process, the copper removal rate may be selectively increased by increasing the concentration of copper metal abrasive particles in the slurry, and the copper removal rate may be selectively decreased by decreasing the concentration of copper metal abrasive particles in the slurry.

### BACKGROUND

Chemical Mechanical Planarization (CMP), also known as chemical mechanical polishing, is one of the primary removal methods used in the manufacturing of integrated circuits because CMP is one of the most effective methods for achieving adequate local and global surface planarization. CMP uses a polishing pad and a slurry to planarize the wafer surface at a number of intermediate stages and as a final step after deposition of various features, interconnects, and coatings.

CMP is used in dual damascene processes for producing final copper interconnects on a wafer. CMP slurries used for copper typically contain abrasive particles such as silicon dioxide (SiO₂), aluminum oxide (Al₂O₃), or cerium oxide (CeO₂). CMP slurries for copper also tend to include an oxidizer species such as hydrogen peroxide (H₂O₂), organic complexing agents, surfactants with both hydrophobic and hydrophilic chemical groups, and/or corrosion inhibitors such as benzotriazole. FIG. 1 illustrates a conventional abrasive particle 100 with surfactants 102. The abrasive particle 100 may be formed using silicon dioxide, aluminum dioxide, cerium oxide, or other conventional abrasive particle materials.

A common problem that occurs during copper CMP is dishing and erosion of the copper surface. Dishing and erosion reduces the final thickness of the copper lines and interconnects and often leads to non-planarity of the copper surface, resulting in larger variations when multi-levels of metal or dielectric are added. It has been shown that dishing and erosion during copper CMP is dependent on geometry, slurry chemistry, the planarization process, and the thickness of the originally deposited copper layer.

One conventional approach to customizing copper removal rates consists of making empirical modifications to the copper CMP process conditions, such as pressure of the polishing pad on the wafer, polishing pad velocity, slurry flow rate, slurry dilution, or other process conditions. Unfortunately, such modifications are time-consuming and limited in effectiveness due to the lack of direct control of the slurry chemical reactivity. Slurry chemical reactivity typically does not remain constant during carious CMP stages, which further complicates empirical modification efforts.

### BRIEF DESCRIPTION OF THE DRAWINGS

FIG. 1 illustrates a conventional abrasive particle used in a copper CMP slurry with surfactants.

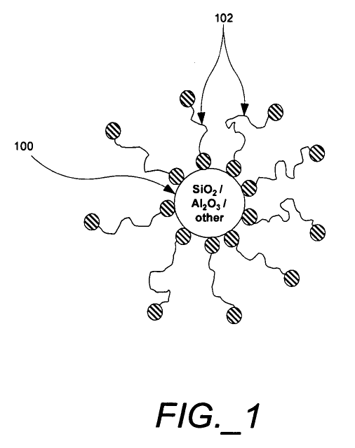

FIGS. 2A and 2B illustrate an abrasive particle used in a copper CMP slurry with surfactants according to an implementation of the invention.

FIGS. 3A and 3B illustrate an abrasive particle used in a copper CMP slurry with surfactants according to another implementation of the invention.

FIG. 4 illustrates the slurry chemistry provided using abrasive particles formed in accordance with the invention.

FIG. 5 is a graph illustrating the improvement in copper removal initiation using abrasive particles formed in accordance with the invention.

### DETAILED DESCRIPTION

Described herein are systems and methods for a chemical mechanical polishing (CMP) slurry using novel abrasive particles that provide improved and controllable removal rates for copper. In the following description, various aspects of the illustrative implementations will be described using terms commonly employed by those skilled in the art to convey the substance of their work to others skilled in the art. However, it will be apparent to those skilled in the art that the present invention may be practiced with only some of the described aspects. For purposes of explanation, specific numbers, materials and configurations are set forth in order to provide a thorough understanding of the illustrative implementations. However, it will be apparent to one skilled in the art that the present invention may be practiced without the specific details. In other instances, well-known features are omitted or simplified in order not to obscure the illustrative implementations.

Various operations will be described as multiple discrete operations, in turn, in a manner that is most helpful in understanding the present invention, however, the order of description should not be construed to imply that these operations are necessarily order dependent. In particular, these operations need not be performed in the order of presentation.

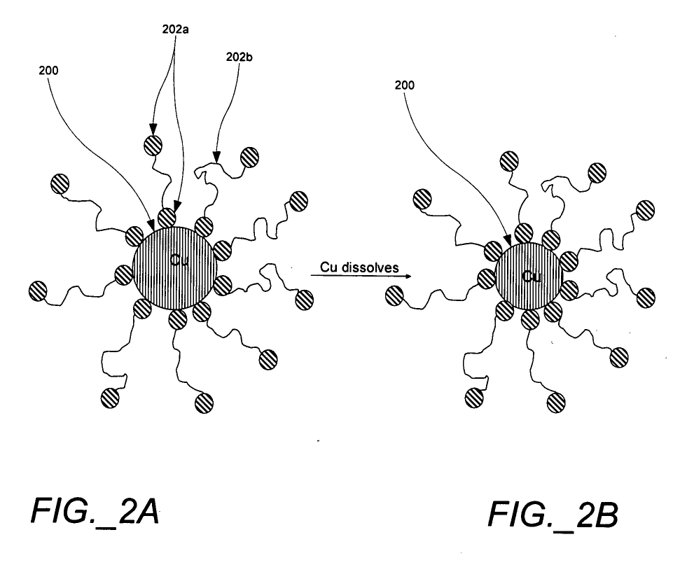

FIG. 2A illustrates a novel abrasive particle 200 formed in accordance with an implementation of the invention. In the implementation shown, the abrasive particle 200 is formed entirely from copper metal or a copper metal alloy. The copper metal abrasive particle 200 replaces conventional abrasive particles used in CMP slurries made from materials such as silicon dioxide, aluminum oxide, or cerium oxide. In some implementations, the diameter of the abrasive particle 200 may be similar to the diameter of those conventional abrasive particles used in CMP slurries. In some implementations, the diameter of the abrasive particle 200 may range from 3 to 500 nanometers (nm). In the implementation shown, the abrasive particle 200 is substantially spherical, while in other implementations the abrasive particle 200 may be formed using other known shapes for particles.

As the abrasive particle 200 is suspended in the CMP slurry, the copper metal in the abrasive particle 200 may oxidize and dissolve into solution. The copper metal may have an oxidized outer layer of CU₂O and/or CuO in solution. The size of the abrasive particle 200 is reduced as the copper metal dissolves, as shown in FIG. 2B. As will be explained below, the copper metal that dissolves into the solution improves the reactivity and provides better control of the CMP slurry.

A CMP slurry to polish a copper-based film or layer may be formed in accordance with the invention using the abrasive particles 200. The CMP slurry of the invention may include surfactants 202 to surround the abrasive particles 200 while they are suspended in the CMP slurry, as shown in FIG. 2A. Each surfactant molecule may include hydrophilic groups 202a and hydrophobic groups 202b. The surfactants 202 may be used to prevent some of the abrasive particles 200 from clustering together and/or from settling out of solution. The CMP slurry of the invention may also include an oxidizer such as hydrogen peroxide (H₂O₂) and a copper complexing agent such as glycine. The abrasive particles may interact with surfactant molecules that contain both hydrophilic (202a) and hydrophobic (202b) ends. The hydrophilic groups 202a may preferentially interact with the surface of the copper coated abrasive particle, in addition to being solvated in the slurry solution. In some implementations, a corrosion inhibitor such as benzotriazole (BTA), and an organic complexing agent may be introduced into the slurry. The organic complexing agent may be an amino acid and its ions, such as glycine, or an organic acid and its ions, such as citric acid.

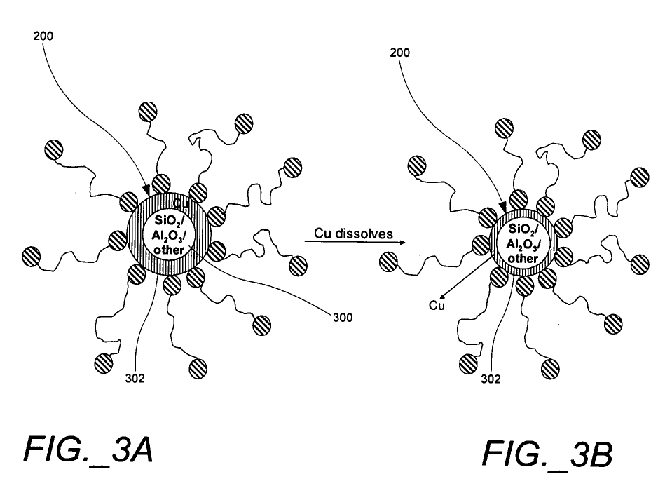

FIG. 3A illustrates another implementation of the abrasive particle 200 that consists of a conventional abrasive particle covered by a copper metal shell. An interior portion 300 of the abrasive particle 200 may be silicon dioxide, aluminum oxide, cerium oxide, or any other material that is generally used to form abrasive particles in CMP slurries. A copper shell 302 of the abrasive particle 200 consists of copper metal. In some implementations, the diameter of this abrasive particle 200 may also range from 3 to 500 nm. As with the copper abrasive particle 200 of FIG. 2B, the size of the abrasive particle 200 of FIG. 3A is reduced as the copper metal dissolves, as shown in FIG. 3B.

In some implementations, the copper shell 302 may be formed over the interior portion 300 using a deposition process such as chemical vapor deposition, atomic layer deposition, or a sputtering process. In some implementations, depending on the material chosen for the interior portion 300, an electroless plating process may be used to form the copper shell 302 over the interior portion 300.

A CMP slurry made in accordance with the invention introduces copper ions that dissolve into the CMP slurry to form copper ion complexes. Detailed quantum chemistry calculations have shown that the presence of copper ion complexes lowers the activation energy barrier necessary for the formation of reactive radicals such as hydroxyl (OH) and hydroperoxyl (OOH) radicals, and thereby increases the probability and rates of formation of these radicals. An increase in reactive radical concentration would generally lead to a corresponding increase in the reactivity of the CMP slurry and hence an increase in the copper removal rate.

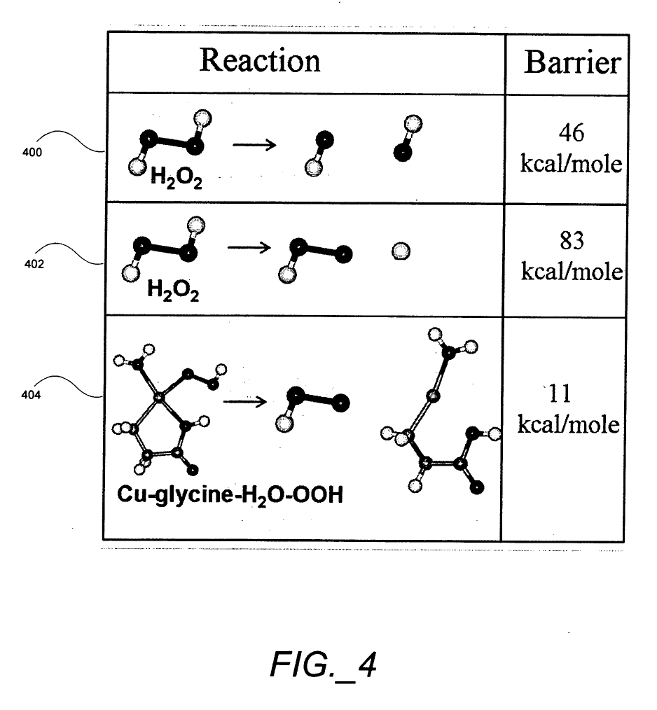

FIG. 4 illustrates quantum chemistry simulation results showing how radicals are formed in both conventional CMP slurries and CMP slurries made in accordance with the invention. In conventional CMP slurries, the formation of reactive radicals requires high activation energy barriers. For instance, the formation of hydroxyl radicals from H₂O₂ (see conventional reaction 400) has an activation barrier of around 46 kcal/mol, while the formation of hydroperoxyl radicals from H₂O₂ (see conventional reaction 402) has an activation barrier of around 83 kcal/mol. These high activation barriers tend to prevent the formation of reactive radicals under typical copper CMP conditions.

In accordance with the invention, reaction 404 shows the end reaction that forms the hydroperoxyl radical using copper ion complexes. The reaction 404 has a low activation energy barrier of around 11 kcal/mol, which is much lower than the activation energy barriers for direct scission of HO—OH (46 kcal/mol) and H—OOH (83 kcal/mol), thus indicating the effects of complexed copper ions in the formation of reactive radicals such as hydroperoxyl. Table 1 shows exemplary reaction mechanisms that may occur in a CMP slurry made in accordance with the invention.

TABLE 1

| | |
|---|---|
| Cu(H₂O)₄²⁺ + glycine → | Cu-glycine-(H₂O)₂²⁺ + 2H₂O |
| H₂O₂ + H₂O [symbol] | OOH⁻ + H₃O⁺ |
| Cu-glycine-(H₂O)₂²⁺ + OOH⁻ → | Cu-glycine-H₂O—OOH⁺ + H₂O |
| Cu-glycine-H₂O—OOH⁺ → | Cu-glycine-H₂O⁺+ OOH^{•} |

In implementations of the invention, a CMP process to polish copper on a substrate can be modified through the selective addition and removal of the copper abrasive particles 200 in the slurry. The addition of the copper abrasive particles 200 into the slurry will enhance the copper removal rate of the CMP process. The removal of the copper abrasive particles 200 from the slurry will reduce the copper removal rate of the CMP process. Accordingly, the addition and/or removal of the copper abrasive particles 200 of the invention during various CMP stages enables the copper removal rate to be increased or decreased depending on what is required. This provides improved control of slurry reactivity and copper removal rate, and provides an effective chemical control strategy to optimize CMP performance and minimize copper loss during clearing. The amount of copper abrasive particles 200 to be added to the slurry may be pre-determined for each particular wafer to be polished, or it may be determined during the CMP process itself and adjusted using a suitable process control strategy.

For instance, the addition of the copper abrasive particles 200 into the slurry at the beginning of the CMP process will increase the copper removal rate, thereby overcoming the typical low removal rate initiation period that occurs in conventional CMP processes for copper. Furthermore, the removal of the copper abrasive particles 200 from the slurry (e.g., by diluting the slurry with a more conventional, copper-free slurry) may be used in stages where a decreased copper removal rate is required, such as during the copper clear or end-pointing stage.

In implementations of the invention, the abrasive particles used in a copper CMP slurry may be only the copper abrasive particles 200. In some implementations, the abrasive particles used in a copper CMP slurry may consist of both the copper abrasive particles 200 as well as conventional abrasive particles formed from materials such as silicon dioxide, aluminum oxide, or cerium oxide. The amounts used for each of these abrasive particles may be modified depending on the wafer characteristics and the CMP process needs.

In one implementation of the invention, the abrasive particles 200 shown in FIGS. 3A and 3B may be used in a CMP process to provide a copper removal rate that begins at a high level and then steadily decreases over the span of the CMP process. The thickness of the copper shell 302 may be fixed such that the copper shell 302 completely dissolves by the time the CMP process reaches a stage where the lowest copper removal rate is required. The CMP process will therefore have a high copper removal rate at the beginning of the process when the copper begins dissolving off the abrasive particle 200, and the copper removal rate will steadily decrease as the amount of copper dissolving off the abrasive particle 200 decreases until all that is left is the interior portion 300. The interior portion 300 will then provide the same abrasive properties as conventional abrasive particles.

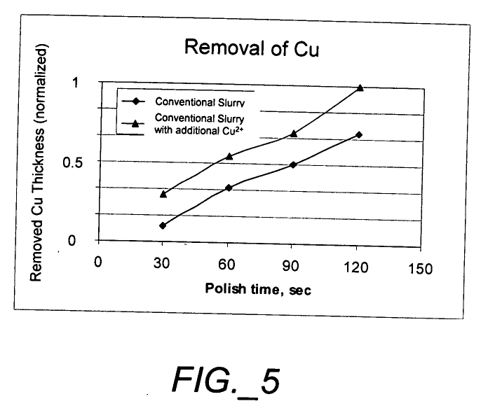

FIG. 5 is a graph showing experimental results of adding a copper salt into a representative CMP slurry formulation for copper. As shown by the graph, an increase in the copper removal rate occurs when the copper salt is included in the copper slurry. For each of the polishing times tested, the addition of the abrasive particles 200 resulted in improved copper polishing rates.

The addition of copper therefore provides an improved and controlled method to modify the copper removal rate of a CMP process using similar process conditions and equipment configurations. The copper abrasive particles 200 provide improved and consistent copper removal that is generally not attainable by simply altering process conditions alone.

The above description of illustrated implementations of the invention, including what is described in the Abstract, is not intended to be exhaustive or to limit the invention to the precise forms disclosed. While specific implementations of, and examples for, the invention are described herein for illustrative purposes, various equivalent modifications are possible within the scope of the invention, as those skilled in the relevant art will recognize.

These modifications may be made to the invention in light of the above detailed description. The terms used in the following claims should not be construed to limit the invention to the specific implementations disclosed in the specification and the claims. Rather, the scope of the invention is to be determined entirely by the following claims, which are to be construed in accordance with established doctrines of claim interpretation.

1. A slurry comprising:
an oxidizer;
an organic complexing agent; and
a plurality of copper metal abrasive particles, wherein the copper metal is capable of dissolving into the slurry.

2. The slurry of claim 1, wherein the slurry is for use in a chemical mechanical polishing process for planarizing copper metal structures on a substrate.

3. The slurry of claim 1, wherein each copper metal abrasive particle is formed entirely of copper metal.

4. The slurry of claim 1, wherein each copper metal abrasive particle is formed entirely of a copper-based alloy.

5. The slurry of claim 1, wherein each copper metal abrasive particle comprises an abrasive material core and a copper metal shell formed around the core.

6. The slurry of claim 5, wherein the abrasive material core comprises silicon dioxide, aluminum dioxide, or cerium oxide.

7. The slurry of claim 6, wherein the copper metal shell comprises a copper-based alloy shell.

8. The slurry of claim 1, wherein a diameter of the copper metal abrasive particles ranges from 3 to 500 nm.

9. The slurry of claim 1, wherein the oxidizer comprises hydrogen peroxide.

10. The slurry of claim 1, further comprising a corrosion inhibitor.

11. The slurry of claim 1, wherein the organic complexing agent comprises an amino acid and its ions.

12. The slurry of claim 11, wherein the amino acid comprises glycine.

13. The slurry of claim 1, wherein the organic complexing agent comprises an organic acid and its ions.

14. The slurry of claim 13, wherein the organic acid comprises citric acid.

15. The slurry of claim 1, further comprising a surfactant.

16. The slurry of claim 1, further comprising a plurality of abrasive particles comprising silicon dioxide, aluminum dioxide, or cerium oxide.

17. The slurry of claim 2, wherein the substrate comprises a semiconductor wafer.

18. The slurry of claim 2, wherein the copper metal structures comprise pure copper interconnects and pure copper vias.

19. The slurry of claim 2, wherein the copper metal structures comprise alloyed copper interconnects and alloyed copper vias.

20. A method comprising:
providing a slurry containing copper metal abrasive particles;
using the slurry to perform a chemical mechanical polishing (CMP) process for planarizing copper-based metal structures on a substrate;
selectively increasing a copper removal rate of the CMP process by increasing the concentration of copper metal abrasive particles in the slurry; and
selectively decreasing the copper removal rate of the CMP process by decreasing the concentration of copper metal abrasive particles in the slurry.

21. The method of claim 20, wherein the increasing of the concentration of copper metal abrasive particles in the slurry comprises adding more copper metal abrasive particles to the slurry.

22. The method of claim 20, wherein the decreasing of the concentration of copper metal abrasive particles in the slurry comprises diluting the slurry.

23. The method of claim 20, wherein the decreasing of the concentration of copper metal abrasive particles in the slurry comprises adding non-copper abrasive particles to the slurry.

24. The method of claim 20, wherein the copper metal abrasive particles are formed from copper metal.

25. The method of claim 20, wherein the copper metal abrasive particles are formed from a copper-based alloy.

26. The method of claim 23, wherein the non-copper abrasive particles comprise abrasive particles formed from silicon dioxide, aluminum dioxide, or cerium oxide.

27. The method of claim 20, wherein the copper removal rate of the CMP process is selectively increased at the beginning of the CMP process.

28. The method of claim 20, wherein the copper removal rate of the CMP process is selectively decreased at the end of the CMP process.

29. A slurry comprising:
an oxidizer;
an organic complexing agent;
a corrosion inhibitor;
a surfactant; and
a plurality of copper metal abrasive particles.

30. The slurry of claim 29, wherein copper from the plurality of copper metal abrasive particles dissolves into the slurry to form copper ion complexes.

31. The slurry of claim 30, wherein the copper ion complexes comprise Cu(HO)₄²⁺.

32. The slurry of claim 30, wherein the presence of the copper ion complexes increases the rate at which reactive radicals are formed.

33. The slurry of claim 32, wherein the reactive radicals comprise hydroxyl and hydroperoxyl radicals.

34. The slurry of claim 29, wherein the organic complexing agent comprises an amino acid and its ions.

35. The slurry of claim 29, wherein the organic complexing agent comprises an organic acid and its ions.

36. The slurry of claim 29, wherein the organic complexing agent comprises glycine.

37. The slurry of claim 29, wherein the organic complexing agent comprises citric acid.

38. The slurry of claim 29, wherein the oxidizer comprises hydrogen peroxide.

39. The slurry of claim 29, wherein the corrosion inhibitor comprises BTA.
